(19) United States
(12) Patent Application Publication
(10) Pub. No.: US 2009/0174069 A1
(43) Pub. Date: Jul. 9, 2009

(54) I/O PAD STRUCTURE FOR ENHANCING SOLDER JOINT RELIABILITY IN INTEGRATED CIRCUIT DEVICES

(75) Inventors: Hau Nguyen, San Jose, CA (US); Luu T. Nguyen, San Jose, CA (US); Anindya Poddar, Sunnyvale, CA (US)

Correspondence Address: Beyer Law Group LLP, P.O. BOX 1687, Cupertino, CA, 95015-1687, US

(73) Assignee: NATIONAL SEMICONDUCTOR CORPORATION, Santa Clara, CA (US)

(21) Appl. No.: 11/969,704

(22) Filed: Jan. 4, 2008

(51) Int. Cl. H01L 23/488

(52) U.S. Cl. 257/737; 257/E23.023

(57) ABSTRACT

A semiconductor device is described. The device includes an integrated circuit die having an active surface that includes a plurality of input/output (I/O) pads. The device further includes a plurality of crack resistant structures. Each crack resistant structure is formed over an associated I/O pad and includes an associated raised portion. Each I/O pad may be bumped with solder such that a solder bump is formed over the associated crack resistant structure on the I/O pad.

### FIELD OF THE INVENTION

The present invention generally relates to integrated circuit (IC) devices. More particularly, the invention relates to the formation of crack resistant I/O pad structures that improve the thermal performance and board level reliability of IC devices.

### BACKGROUND OF THE INVENTION

There are a number of conventional processes for packaging integrated circuit (IC) dice. In many applications it is desirable to form solder bumps directly on input/output (I/O) pads on the active surface of an IC die. Typically, the solder bumps are formed on the active surface of the wafer before the individual dice are singulated from a wafer. When the resulting die is mounted onto a printed circuit board (PCB) or other appropriate carrier, the solder bumps may be reflowed to create electrical connections between the die and PCB. This style of electrically connecting IC dice is often called “flip-chip” mounting because the die is generally “flipped” in order to position the solder bumps on its active surface onto associated contacts on the surface of the substrate to which the die is to be attached.

During operation cycles of the die, differences in the coefficients of thermal expansion (CTE) between the PCB and the die can result in significant thermal stresses as the temperature of the die is cyclically increased and decreased. These stresses can be particularly problematic in regions surrounding the interfaces of the solder connections and can result in cracking. A crack may continue to propagate until the solder connection is severed and the physical and electrical connection between the I/O pad and the contact is terminated thereby generally rendering the device inoperable.

Accordingly, although existing packaging techniques work well, there are continuing efforts to develop even more efficient designs and methods for surface mounting IC dice that improve the thermal performance of the dice.

### SUMMARY OF THE INVENTION

In one aspect of the invention, a semiconductor device is described. The device includes an integrated circuit die having an active surface that includes a plurality of input/output (I/O) pads. The device further includes a plurality of crack resistant structures. Each crack resistant structure is formed over an associated I/O pad and includes an associated raised portion that has a diameter that is smaller than a diameter of the associated I/O pad and a top surface that is elevated relative to the topmost surface of any region surrounding the raised portion and overlying the I/O pad. Each I/O pad may be bumped with solder such that a solder bump is formed over the associated crack resistant structure on the I/O pad.

In various embodiments, the device is mounted onto a printed circuit board (PCB) and the solder bumps are reflowed to form solder joints that physically and electrically connect the I/O pads and overlying crack resistant structures to associated contacts on the PCB. During operation of the device the raised portion of the crack resistant structure prevents the propagation of cracks through the raised portion and across the I/O pad.

The crack resistant structures can be formed in a wide variety of shapes and geometries. In some embodiments the raised portion of the crack resistant structure takes the form of a solid or hollow cylinder, by way of example.

In another aspect, an arrangement is described that includes a semiconductor wafer. The wafer includes a large number of integrated circuit dice, such as the die just described above, each having crack resistant structures formed over the I/O pads on the active surfaces of the dice.

These and other features, aspects, and advantages of the invention will be described in more detail below in the detailed description and in conjunction with the following figures.

### BRIEF DESCRIPTION OF THE DRAWINGS

For a better understanding of the invention, reference should be made to the following detailed description taken in conjunction with the accompanying drawings, in which:

FIG. 1 illustrates an example integrated circuit die.

FIGS. 2A-2D illustrate diagrammatic cross-sectional side views of an example I/O pad structure.

FIGS. 3A-3C illustrate diagrammatic cross-sectional side views of an I/O pad structure having a crack resistant projection in accordance with an embodiment of the present invention.

FIGS. 4A-4C each illustrate diagrammatic top and side views of crack resistant projections in accordance with embodiments of the present invention.

Like reference numerals refer to corresponding parts throughout the drawings.

### DETAILED DESCRIPTION OF PARTICULAR EMBODIMENTS

The present invention generally relates to integrated circuit (IC) devices. More particularly, the invention relates to the formation of crack resistant I/O pad structures that improve the thermal performance of IC devices.

In the following description, numerous specific details are set forth to provide a thorough understanding of the present invention. It will be apparent, however, to one skilled in the art that the present invention may be practiced without some or all of these specific details. In other instances, well known process steps have not been described in detail in order to avoid unnecessary obscuring of the present invention.

The following description focuses on the preparation of IC dice that utilize solder bump joints in connecting I/O pads on the active surfaces of the dice with external contacts. One class of IC devices in which aspects of the present invention are applicable are referred to as surface mount devices (SMDs). SMDs are IC dice or IC die packages that are intended to be mounted directly to surface contacts (contact pads) on the surface of a printed circuit board (PCB). Such applications are generally known as chip on board (COB) applications.

One particular relatively new subclass of SMDs are known as micro SMDs (also “μSMDs”). Micro SMDs are chip scale packages (CSPs) in which the footprint of the package is substantially the same as the footprint of the associated die. Generally, a CSP must have a footprint no greater than 1.2 times that of the footprint of the associated packaged die. Typical micro SMDs have a footprint that is less than 2 mm by 2 mm square and some micro SMDs have lengths and widths less than 1 mm. Micro SMDs are a special class of CSPs that are referred to as wafer level packages (WLPs). A WLP is a special variety of CSP in which the dice are packaged and prepared for subsequent attachment at the wafer level. More specifically, the final I/O pads on the dice may be redistributed and solder bumped at the wafer level to facilitate direct connection of each die to contacts on a PCB upon singulation of the wafer. Micro SMDs offer small footprints, high I/O densities, better electrical and thermal performance than comparable wire-bonded packages and high moisture sensitivity level (MSL) performance, among other advantages. As such, micro SMDs are particularly desired in mobile power applications.

However, although described in the context of CSP, WLP and SMD embodiments, it will be appreciated by those skilled in the art that the present invention is not limited to CSP, WLP and SMD embodiments, and that the I/O pad structures described herein may be incorporated with dice that are packaged using a wide variety of intermediary substrates such as leadframes and ball grid arrays (BGAs), among others.

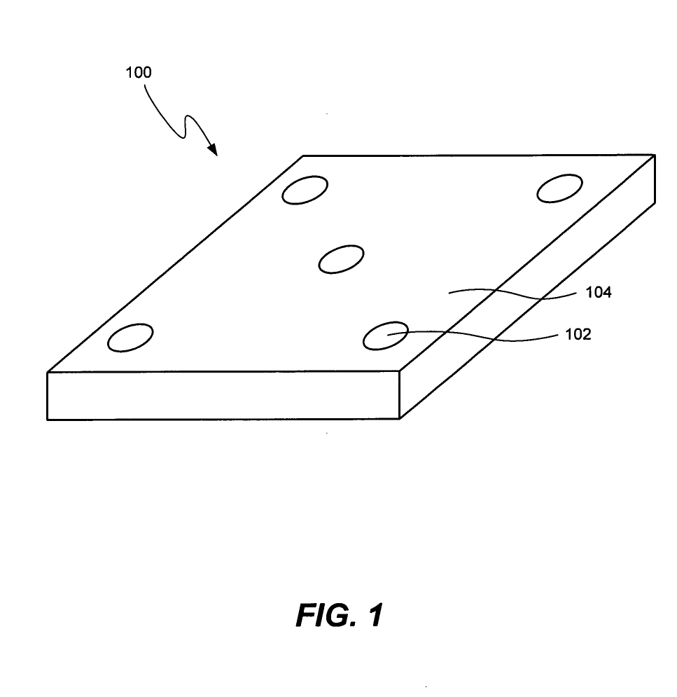

Referring initially to FIG. 1, an example IC die 100 will be described. IC die 100 includes a plurality of input/output (I/O) pads 102 formed on the active surface 104 of the die 100. As will be appreciated by those familiar with the art, the I/O pads 102 may be the original bond pads on the original active surface of the die, but are more often bond pads that have been redistributed from the original bond pads using conventional redistribution techniques. More particularly, it is often advantageous to redistribute the original bond pads using metal redistribution lines to form a desired final I/O bond pad array layout (hereinafter a “final I/O bond pad” will also be referred to as an “I/O pad”). By way of example, copper redistribution lines are often used to electrically route the original bond pads to the I/O pads 102 which are positioned at desired locations.

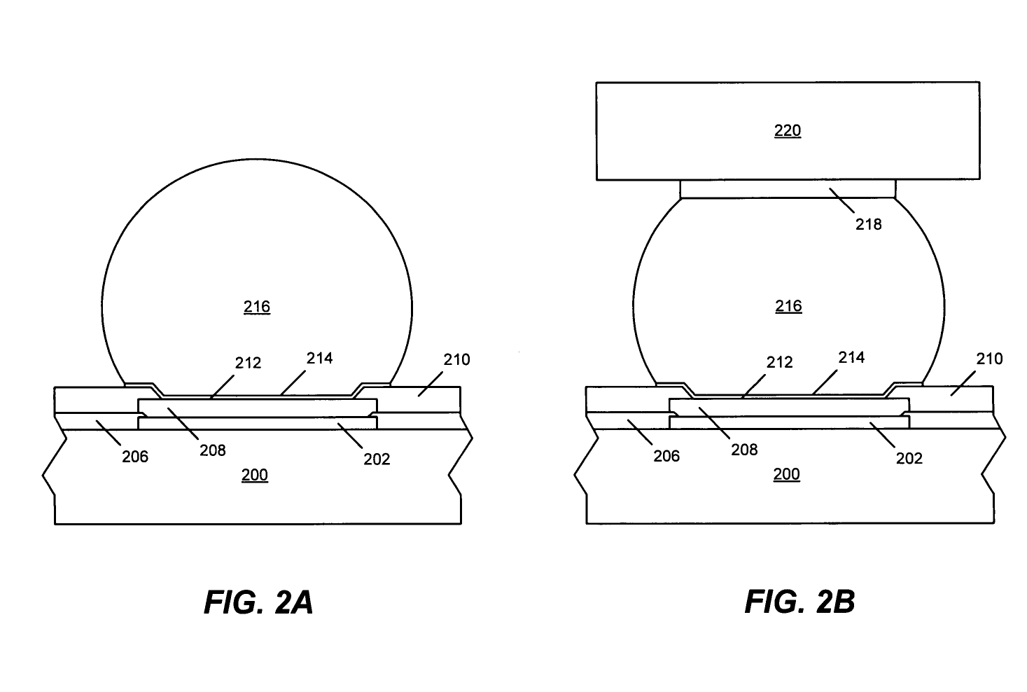

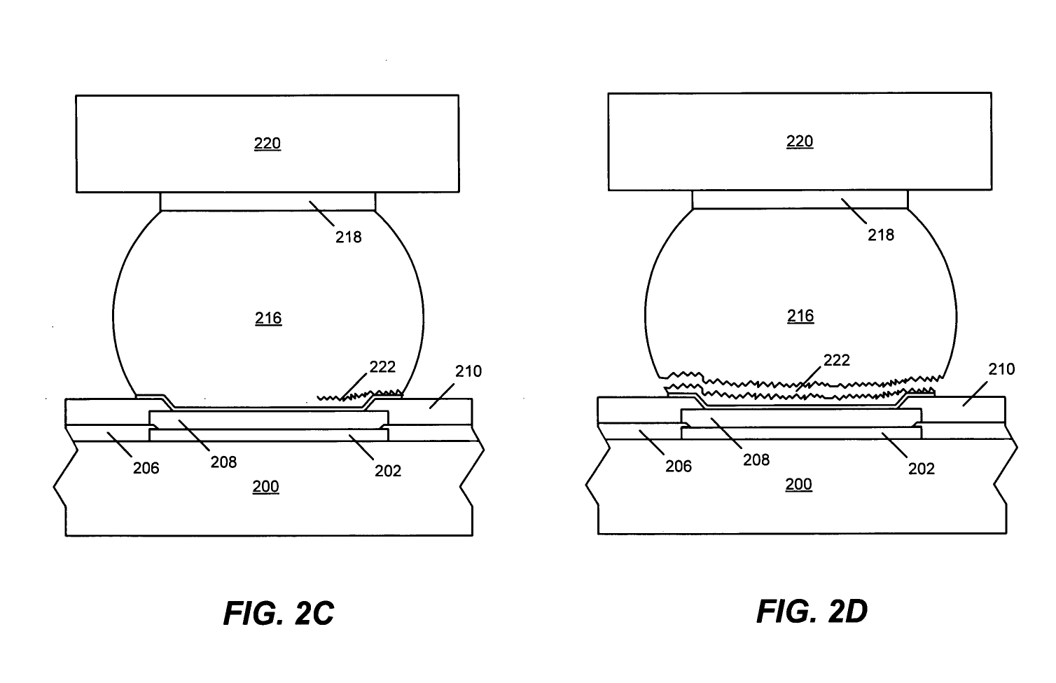

FIG. 2A illustrates an example of a conventional I/O pad structure on the active surface of a die 200. The active side of a die generally includes a multiplicity of alternating dielectric and metallization layers which overlie the active circuits in the die. The metallization layers serve as electrical routing layers and are interconnected at various locations with conductive vias. Selected portions of the topmost metallization layer are left exposed through various openings in the outermost dielectric or passivation layer 206 on an active surface of each die 202 to form a plurality of bond pads 202 that serve as electrical contacts for the die 200. Generally, the topmost metallization layer that forms the bond pads 202 is formed from aluminum (Al) or an aluminum alloy although any suitable material may be used. In silicon devices, the passivation layer 206 is often formed from silicon oxide or various other oxides and/or nitrides, for example.

The bond pads 202 themselves may serve as I/O pads that can then be electrically connected to an external device, such as a PCB, using conventional techniques. However, it is often desirable to redistribute these original bond pads 202. By way of example, in some applications it may be necessary to redistribute the bond pads 202 to match a corresponding layout of contacts on the surface of a PCB. It may also be advantageous to enlarge the surface area available for bonding on a bond pad. As such, one or more metal redistribution layers may be deposited over the active surface of the die 200, including portions of the original bond pads 202, and used to redistribute and/or resize the original (e.g., aluminum) bond pads 202. The redistribution layers may be formed at the wafer level using any suitable process and any suitable conductive material or materials, such as copper (Cu) or a copper alloy, for example.

In the illustrated example, a copper redistribution layer 208 is deposited over the original aluminum bond pad 202 to form a new I/O pad 212. In the illustrated example, the copper layer 208 is deposited over the edges of the passivation layer 206 that surround the bond pad 202. In this way, the aluminum bond pad 202 is entirely covered by either the passivation layer 206 or the redistribution layer 208. A second repassivation layer 210 is deposited over and around the edges of the copper layer 208. As is known in the art, benzocyclobutene (BCB) is generally used to form the repassivation layer 210, although any suitable dielectric or passivation material such as polyimide (PI), polybenzooxazole (PBO), polysiloxane and polydimethylsiloxane, among others, may be used.

In the example illustrated in FIG. 2A, the exposed surface of the copper layer 208, which forms the I/O pad 212 is further covered by an underbump metallization (UBM) layer or layers 214. As will be appreciated by those familiar with the art, UBMs are often formed over bond pads to provide a better bonding surface for the associated solder bumps. Generally, UBMs are comprised of multiple overlapping metallic layers having the combined features of adhesion, diffusion barrier, wetting and oxidation protection. Typically, the UBM layer(s) 214 is deposited via sputtering at the wafer level prior to singulation of the wafer. Typical UBM materials include, by way of example, one or more of tungsten, copper, nickel vanadium, aluminum, titanium, cobalt, and gold, among others, and in various combinations such as TiCu, TiWCu, TiWCuNi, TiWCuNiAu, TiNiPd and AlNiVCu.

Solder bumps 216 are formed over the I/O pads 212. Generally, solder bumping is performed at the wafer level using any of a number of conventional processes such as, by way of example, ball-dropping preformed solder balls on the I/O pads 212, electroplating a solder layer over the I/O pads, or screen printing a solder paste over the I/O pads. A wide variety of conventional solder materials may be used to form the solder bumps 216, such as, for example, an alloy of SnAgCu. As illustrated in FIG. 2A, the solder bump 216 typically spreads across the entire surface of the UBM layer 214.

During attachment of the die 200 to a PCB 220, the solder bumps 216 are reflowed to form solder joints 216 that physically and electrically connect the I/O pads 212 with corresponding contacts 218 on the PCB 220. FIG. 2B diagrammatically illustrates the I/O pad structure of FIG. 2A attached to a contact 218 on PCB 220. During operation cycles of the device, differences in the coefficients of thermal expansion (CTE) between the PCB 220 and the silicon die 200 result in significant thermal stresses as the temperature of the die is cyclically increased and decreased. These stresses are particularly problematic in regions surrounding the interfaces of the solder joints 216 and I/O pads 212 and can result in cracking. FIG. 2C illustrates a crack 222 propagating inward in the proximity of the interface between the I/O pad 212 and solder joint 216 of FIG. 2B. Typically, the crack 222 will continue to propagate until the solder joint 216 is severed and the physical and electrical connection between the I/O pad 212 and the contact 218 is terminated as illustrated in FIG. 2D thereby generally rendering the device inoperable.

The aforementioned crack propagation mechanism occurs during thermal cycling of the die after mounting to a PCB. However, failures can also occur during drop testing of the component, a test commonly used for all portable products. In this test, components (e.g., die) are assembled onto a PCB, which is mounted onto a heavy anvil and dropped from a fixed vertical distance in order to impart a known impact force and deceleration to the assembly. Test conditions, including the preferred equipment, are outlined in the JEDEC specification JESD22-B111. In drop tests, cracks are initiated and propagated across the solder joints, or through the brittle intermetallic compound layer. By introducing the crack arresting features described below, more energy is required for crack growth resulting in solder joint strength enhancement.

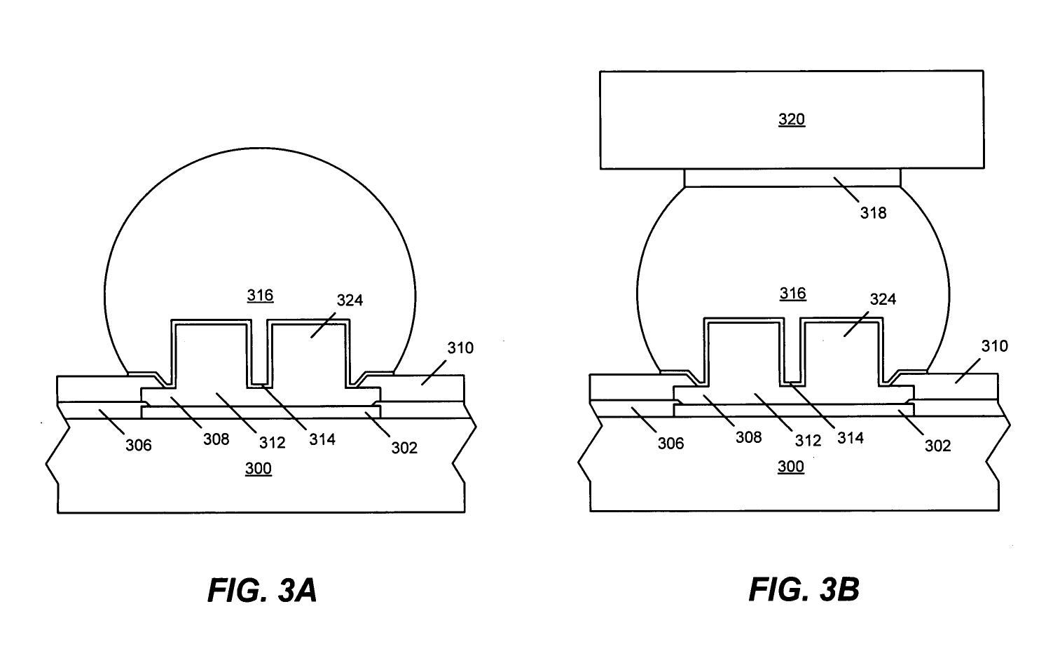

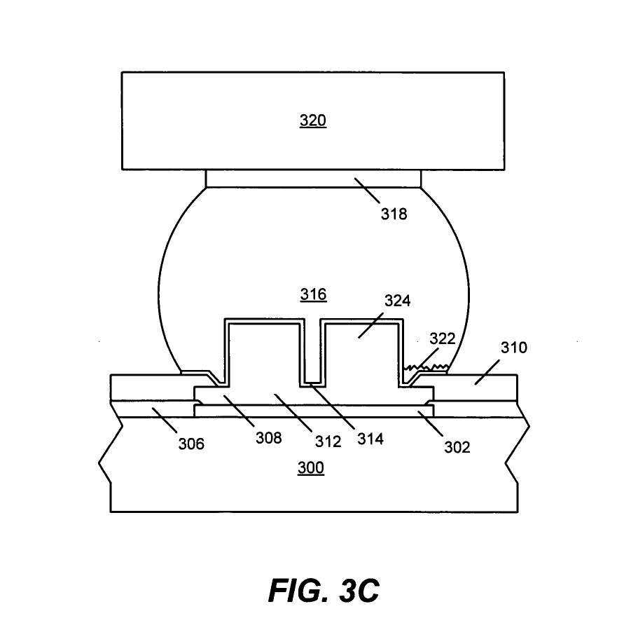

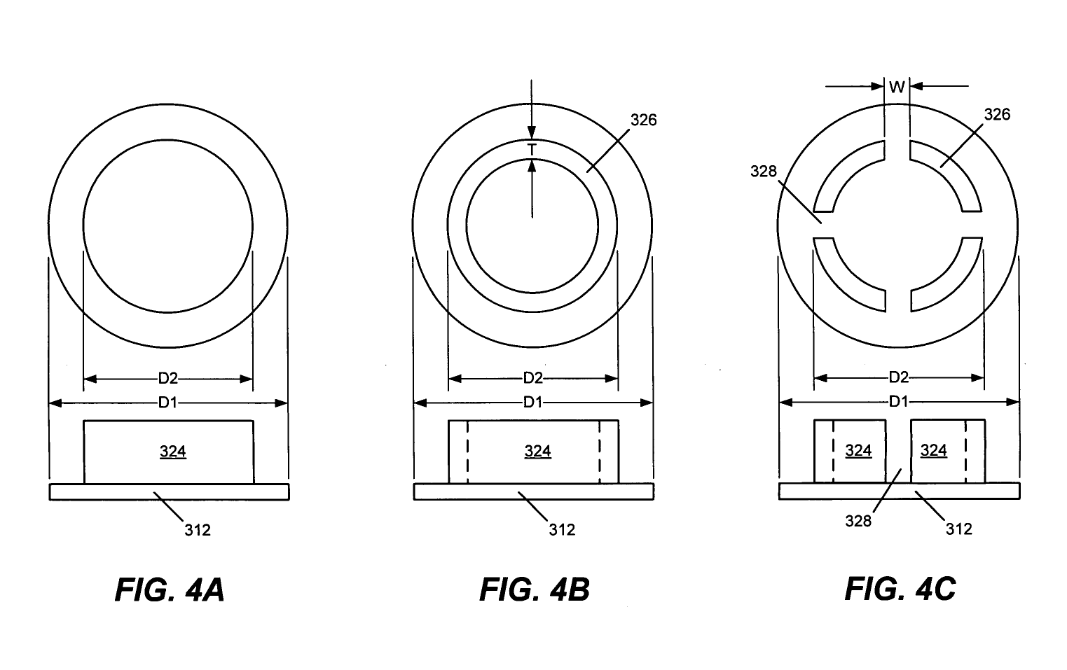

Particular embodiments of the present invention will now be described with reference to FIGS. 3-4. In one embodiment, an IC die is described having I/O pad structures that resist crack propagation through associated solder bumps. According to the embodiments described herein, the crack resistant I/O pad structures are formed over corresponding I/O pads on the active surfaces of dice at the wafer level before the wafer is singulated to produce individual IC dice.

FIG. 3A illustrates an I/O pad structure that resists crack propagation in accordance with one embodiment of the present invention. Similar to the I/O pad structure of FIG. 2A, the I/O pad structure of FIG. 3A includes an original bond pad 302 exposed through an opening in a passivation layer 306 on the active surface of a die 300. Additionally, in the illustrated embodiment, a metal (e.g., Cu) redistribution layer 308 is used to form a final I/O pad 312 that is redistributed and/or resized from the bond pad 302. As in the example of FIG. 2A, a repassivation layer 310 is deposited over and around the edges of the redistribution layer 308 and a UBM layer 314 is deposited over portions of the redistribution layer not covered by the repassivation layer.

The I/O pad structure illustrated in FIGS. 3A-C further includes one or more crack resistant projections 324 over the redistribution layer 308. Each crack resistant projection 324 is formed from a material having sufficient hardness to arrest or deflect the propagation of a crack 322 at the projection as illustrated in FIG. 3C. According to one embodiment, the crack resistant projections 324 are integral with the redistribution layer 308 and formed at the time of deposition of the redistribution layer and of the same material (e.g., Cu) that forms the redistribution layer. Alternatively, in other embodiments, the crack resistant projections 324 may be formed on top of the redistribution layer 308 after deposition of the redistribution layer and/or from a different material than that which forms the redistribution layer. It should also be noted that the crack resistant projections 324 may be formed directly on the original bond pads 302 in embodiments not including a redistribution layer 308. Additionally, in the illustrated embodiment, the crack resistant projections 324 are also covered by a UBM layer(s) 314.

The crack resistant projections 324 may assume a wide variety of shapes and geometries. By way of example, FIGS. 4A-C each illustrate a diagrammatic top view (top) and side view (bottom) of an embodiment of the crack resistant projection 324. In the embodiment illustrated in FIG. 4A, the projection 324 takes the form of a pillar or solid cylinder on top of the bond pad 312. The diameter D2 of the cylinder 324 may vary widely according to the size of the I/O pad 312, among other factors. However, in some embodiments a diameter D2 in the range of approximately 40 to 70 percent of the thickness of the diameter D1 of the I/O pad 312 works well. The height H of the cylinder may also vary widely, but heights in the range of approximately 15 to 50 μm generally work well for many solder bump heights, which, in some embodiments, may be in the range of approximately 100 to 250 μm.

FIG. 4B illustrates another embodiment in which the crack resistant projection 324 takes the form of a hollow cylinder. The dimensions of the hollow cylinder may be similar to those described with reference to the solid cylinder of FIG. 4A. The thickness T of the wall 326 of the hollow cylinder 324 may also vary widely, but in some embodiments thicknesses in the range of approximately 10 to 50 μm work well. In an additional benefit, the hollow cylinder 324 is self-aligning; that is, during solder ball dropping, the hollow cylinder naturally aids in aligning the solder ball with itself and hence the I/O pad 312.

FIG. 4C illustrates yet another embodiment in which the crack resistant projection 324 takes the form of a hollow cylinder having relief notches 328 in the wall 326 of the cylinder. During solder bumping, the notches 328 enable any air trapped within the hollow cylinder 324 to escape thereby preventing air bubbles in the solder. Although illustrated with four notches 328, it will be appreciated that any suitable number of notches may be used.

Although only a few embodiments of crack resistant projections 324 have been described, it will be appreciated by those of skill in the art that a wide variety of other projection shapes and geometries that are suitable for stopping or deflecting crack propagation may be utilized on top of the I/O pads 312 as well.

In some embodiments, the die 200 may be encapsulated with a molding material prior to or after attachment of the die to a PCB. Additionally, in some embodiments an underfill material is applied between the active surface of the die 200 and the surface of the PCB. Molding and/or underfill materials may aid in reducing stresses at the interfaces between the solder joints 316 and the I/O pads 312 or contacts 318. Thus, although the described invention is particularly well suited for applications in which a molding material and/or underfill material are not used, it will be understood that in some embodiments it may be desirable to apply an underfill material and/or encapsulate portions of the die with a molding material.

Although embodiments of the present invention have been described with reference to flip-chip mounting a die to a PCB, it will be apparent to those having skill in the art that particular embodiments described above may be practiced in applications in which a die is mounted to other substrates such as, by way of example, leadframes or those used in a ball-grid array (BGA) packages as well.

The embodiments were chosen and described in order to best explain the principles of the invention and its practical applications, to thereby enable others skilled in the art to best utilize the invention and various embodiments with various modifications as are suited to the particular use contemplated. It is intended that the scope of the invention be defined by the following claims and their equivalents.

What is claimed is:

1. A semiconductor device, comprising
an integrated circuit (IC) die, the die having an active surface having a plurality of input/output (I/O) pads formed thereon;
a plurality of crack resistant structures, each crack resistant structure being formed over an associated I/O pad, each crack resistant structure including an associated raised portion, each raised portion having a diameter that is substantially smaller than a diameter of the associated I/O pad and a top surface that is substantially elevated relative to the topmost surface of any region surrounding the raised portion and overlying the I/O pad.

2. A device as recited in claim 1, further comprising a plurality of solder bumps, each solder bump being formed over an associated crack resistant structure such that the solder bump substantially covers the crack resistant structure.

3. A device as recited in claim 2, wherein each crack resistant structures aids in aligning the associated solder bump with the associated I/O pad.

4. A device as recited in claim 2, wherein the device is mounted onto a printed circuit board (PCB), and wherein the solder bumps physically and electrically connect the I/O pads and overlying crack resistant structures to associated contacts on the PCB.

5. A device as recited in claim 1, whereby during operation of the device the raised portion of the crack resistant structure prevents the propagation of cracks through the raised portion and across the I/O pad.

6. A device as recited in claim 1, wherein the raised portion of each crack resistant structure has a height in the range of approximately 15 to 50 μm.

7. A device as recited in claim 1, wherein the diameter of the raised portion is in the range of approximately 40 to 70 percent of the diameter of the associated I/O pad.

8. A device as recited in claim 1, wherein the raised portion of each crack resistant structure takes the form of a pillar.

9. A device as recited in claim 1, wherein the raised portion of each crack resistant structure takes the form a hollow cylinder.

10. A device as recited in claim 1, wherein the raised portion of each crack resistant structure includes notches for allowing trapped air to escape the crack resistant structures during solder bumping.

11. A device as recited in claim 1, wherein the I/O pad structure is comprised of copper or a copper alloy.

12. A device as recited in claim 1, further comprising an underbump metallization (UBM) layer deposited directly over the crack resistant structure.

13. A device as recited in claim 1, wherein the I/O pads are redistributed from other bond pads.

14. An arrangement, comprising:
a semiconductor wafer including a multiplicity of integrated circuit dice arranged therein, each die having an active surface and a back surface, each back surface being substantially opposite the active surface, the back surfaces of the dice cooperating to form the back surface of the wafer;
a multiplicity of I/O pads, the I/O pads being arranged such that each die includes a plurality of I/O pads on the active surface of the die; and
a multiplicity of crack resistant structures, each crack resistant structure being formed over an associated I/O pad, each crack resistant structure including an associated raised portion, each raised portion having a diameter that is substantially smaller than a diameter of the associated I/O pad and a top surface that is substantially elevated relative to the topmost surface of any region surrounding the raised portion and overlying the I/O pad.

15. An arrangement as recited in claim 14, further comprising a plurality of solder bumps, each solder bump being formed over an associated crack resistant structure such that the solder bump substantially covers the crack resistant structure.

16. An arrangement as recited in claim 14, whereby during operation of the device the raised portion of the crack resistant structure prevents the propagation of cracks through the raised portion and across the I/O pad.

17. An arrangement as recited in claim 14, wherein the raised portion of each crack resistant structure takes the form of a pillar.

18. An arrangement as recited in claim 14, wherein the raised portion of each crack resistant structure takes the form a hollow cylinder.

19. An arrangement as recited in claim 14, wherein the raised portion of each crack resistant structure includes notches for allowing trapped air to escape the crack resistant structures during solder bumping.
